(19) United States
(12) Patent Application Publication
(10) Pub. No.: US 2005/0277281 A1
(43) Pub. Date: Dec. 15, 2005

(54) Compliant interconnect and method of formation

(76) Inventors: Valery M. Dubin, Portland, OR (US); Richard D. Emery, West Hartford, CT (US); Ming Fang, Portland, OR (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/864,957

(22) Filed: Jun. 10, 2004

(51) Int. Cl. H01L 21/44; H01L 21/4763

(52) U.S. Cl. 438/618; 438/611; 438/652; 438/666; 438/619

(57) ABSTRACT

A method for making a compliant interconnect with two or more layers of metal is described herein.

### TECHNICAL FIELD & BACKGROUND

The present invention is related to the fields of electronics and Microelectromechanical Systems (MEMS). In particular, the present invention is related to electrical packaging of integrated circuits, circuit boards, electrode arrays, or other devices with compliant interconnects.

In ultra low k-ILD (interlayer dielectric) technology, the stress on the ILD layers should be minimized. Compliant interconnects, and inexpensive methods to make the same, with the modulated compliance to minimize the effects of mechanical and thermal stress on the ultra low-k ILD layers while still providing sufficient load bearing capability are useful. It is also beneficial that these interconnects have low electro migration, high corrosion resistance and good wettability characteristics.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates a cross sectional view of a portion of a component with compliant interconnect, in accordance with one embodiment;

FIGS. 2a-2i illustrate a method for making the compliant interconnect of FIG. 1, in accordance with one embodiment; and

FIGS. 3a-3j illustrate a method for making the compliant interconnect of FIG. 1, in accordance with another embodiment; and

FIG. 4 illustrates a system having the component of FIG. 1 in accordance with one embodiment.

FIG. 5 illustrates a cross sectional view of a portion a die and a substrate with compliant interconnect of component of FIG. 1 in-between in accordance with one embodiment.

### DETAILED DESCRIPTION OF ILLUSTRATIVE EMBODIMENTS

Embodiments of the present invention include, but are not limited to a method for making compliant interconnects comprising of spring like metal layers and an outer refractory metal layer.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

The elements shown and represented in the various figures do not indicate relative thickness, scale or proportion.

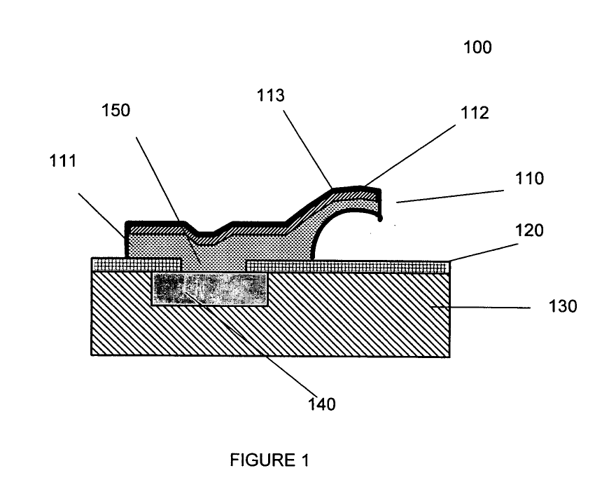

Referring now to FIG. 1, wherein a cross sectional view of a portion of a compliant interconnect in accordance with one embodiment, in the context of a component, is shown. As illustrated, for the embodiment, component 100 includes a metal pad (hereinafter, simply pad) 140. Further, component 100 includes a passivation layer (or dielectric layer) 120 disposed on a substrate 130 with an opening 150 exposing the pad 140 and compliant interconnect 110 is electrically coupled to pad 140.

As will be described in more detail below, compliant interconnect 110 includes two or more metal layers deposited upon each other with the last (outer) layer including refractory metal. Resultantly, the compliant interconnect may exhibit greater improved electron migration, corrosion resistance and/or wettability than otherwise would be expected.

For the embodiment, in addition to the outer refractory metal layer, two metal layers, a seed metal layer 111, and a spring metal layer 112, are illustrated for the embodiment of FIG. 1. Each of metal layers 111, 112 may be formed employing a metal such as aluminum (Al) copper (Cu), titanium (Ti), nickel (Ni), platinum (Pt), gold (Au), silver (Ag), tin (Sn), tantalum (Ta), molybdenum (Mo), chromium (Cr), cobalt (Co), or other materials with like properties and alloys of these materials. The two metal layers 111-112 may be constituted with different metals.

It should be noted that while two metal layers 111-112, in addition to the outer refractory metal layer, are shown in FIG. 1, in alternate embodiments, interconnect 110 may consist of only two metal layers, a spring metal layer and the outer refractory metal layer. In yet other embodiments, interconnect 110 may comprise more than 3 layers, e.g. a seed metal layer, two or more spring metal layers, and the outer refractory metal layer.

As alluded to earlier, the third/outer refractory metal layer 113 is provided to enhance electron migration, corrosion resistance and/or wettablility characteristics. The refractory metal layer may be formed by employing a metal such as cobalt (Co), nickel (Ni), gold (Au), platinum (Pt), palladium (Pd), iridium (Ir), osmium (Os), ruthenium (Ru), rhodium (Rh), silver (Ag), and alloys of these materials. In alternate embodiments, the refractory metal layer may be further combined with a metal such as tungsten (W), molybdenum (Mo), rhenium (Re), tantalum (Ta), niobium (Nb), zirconium (Zr), hafnium (Hf), osmium (OS), or other materials with like properties, and alloys of these materials. In another alternate embodiments, the refractory metal layer 113 may be further combined with an element such as phosphorus (P), nitrogen (N), boron (B), or other materials with like properties.

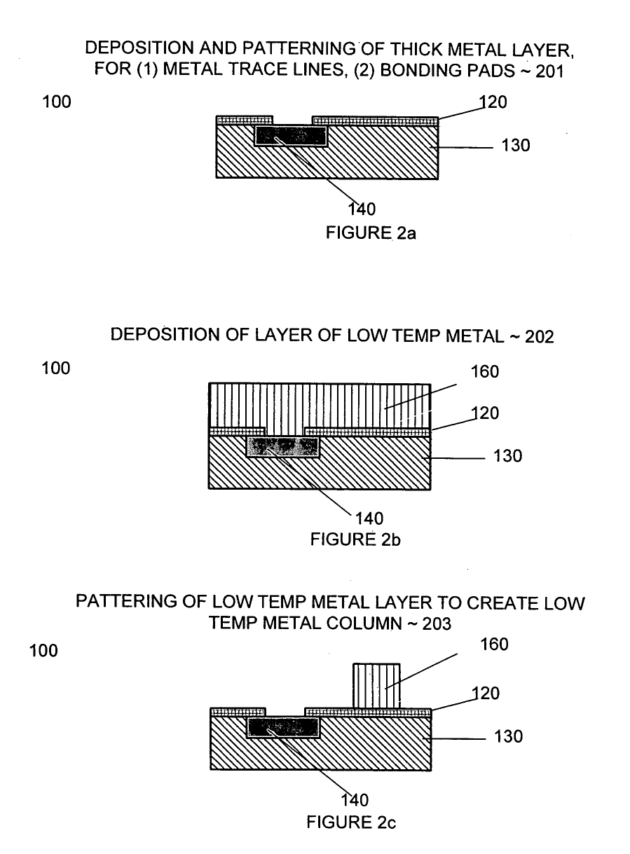

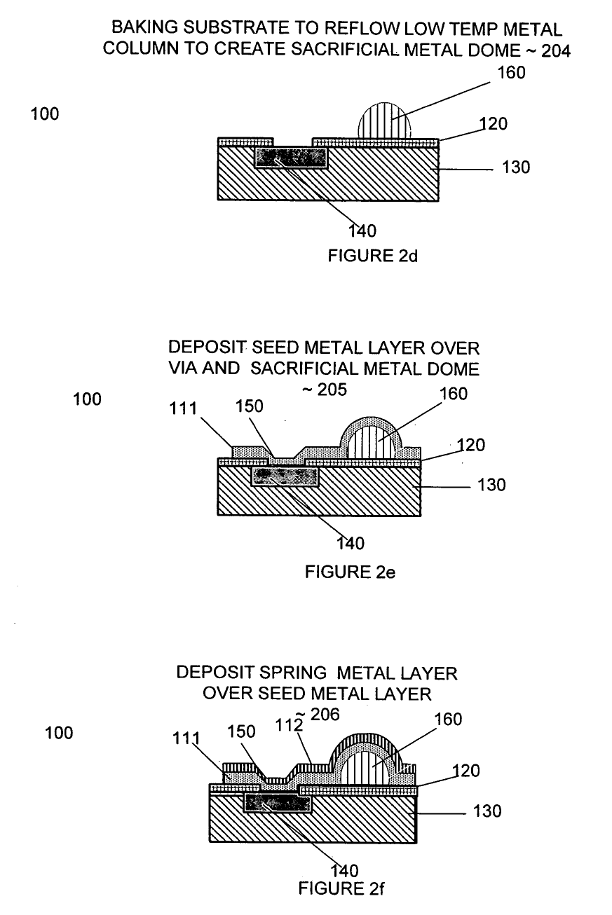

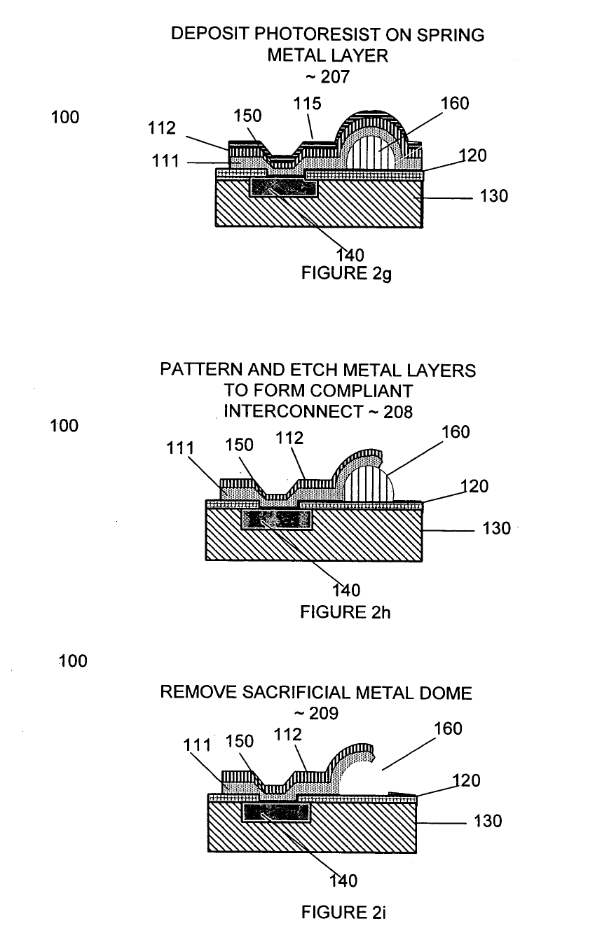

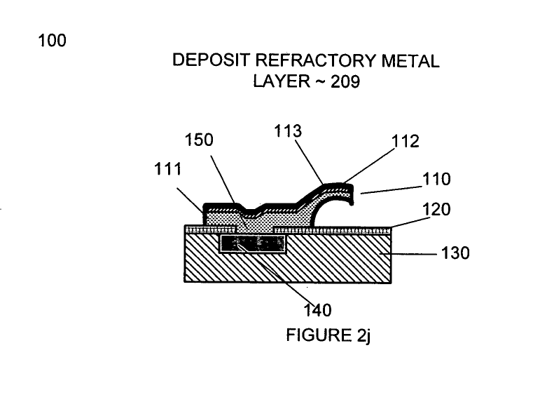

FIGS. 2a-2i illustrate a method of making component 100 in accordance with one embodiment. For the embodiment, component 100 includes a compliant interconnect with a seed metal layer and an outer refractory metal layer.

As illustrated, the method starts with the formation of substrate 130 with pad 140 and an opening 150 exposing the pad 140 employing any one of a number of techniques, op 201. In various embodiments, substrate 130 may be a silicon (Si) substrate, and passivation layer 120 may be formed employing silicon nitride (SiN), and deposited in any one of a number of techniques. In other embodiments, layer 120 may have a polyimide layer 130. The materials listed for the passivation layer 120 are illustrative only; any number of suitable materials may alternately be used to form the layer.

Then, a metal layer 160 is deposited on a top side of dielectric layer 120, op 202. The metal layer may be formed by employing a metal with a low reflow temperature, such as tin (Sn), indium (In), bismuth (Bi), zinc (Zn), and other materials with like properties and alloys of these materials.

Next, metal layer 160 is patterned to create metal column 160, op 203.

Then, metal column 160 may be reflowed into sacrificial metal dome 160 in a number of application dependent manners. The temperature and the time, the amount of heat is applied, are dependent on the composition of the sacrificial metal, the size of column, and heat sensitivity, if any, of the surrounding structures.

Next, for the embodiment, a seed metal layer 111 is deposited on the dielectric layer 120 over the opening 150 and the sacrificial metal dome 160, op 205. In various embodiments, seed metal layer 111 may be deposited by employing a method such as sputtering, chemical vapor deposition, physical vapor deposition, atomic layer deposition, electro plating or electroless plating. In alternate embodiments, the compliant interconnect may be formed without employing a seed metal layer.

Then, for the embodiment, upon forming seed metal layer 111, a spring metal layer 112 is deposited on top of the seed metal layer 111, op 206. In various embodiments, spring metal layer 112 is deposited by electro plating. In other embodiments, spring metal layer 112 is deposited by electroless plating.

Then, a photo resist 115 is formed on top of the spring metal layer 112, and patterned, op 207.

Next, the excess of the seed metal layer 111 and the spring metal layer 112 are removed, e.g. by etching, op 208.

Then, the photo resist is stripped, and the sacrificial metal dome 160 is removed by selective etching, op 209.

Finally, the refractory metal layer 113 is deposited, op 210. In various embodiments, refractory metal layer 113 is deposited by electroless plating. In other embodiments, refractory metal layer 113 is deposited by electro plating.

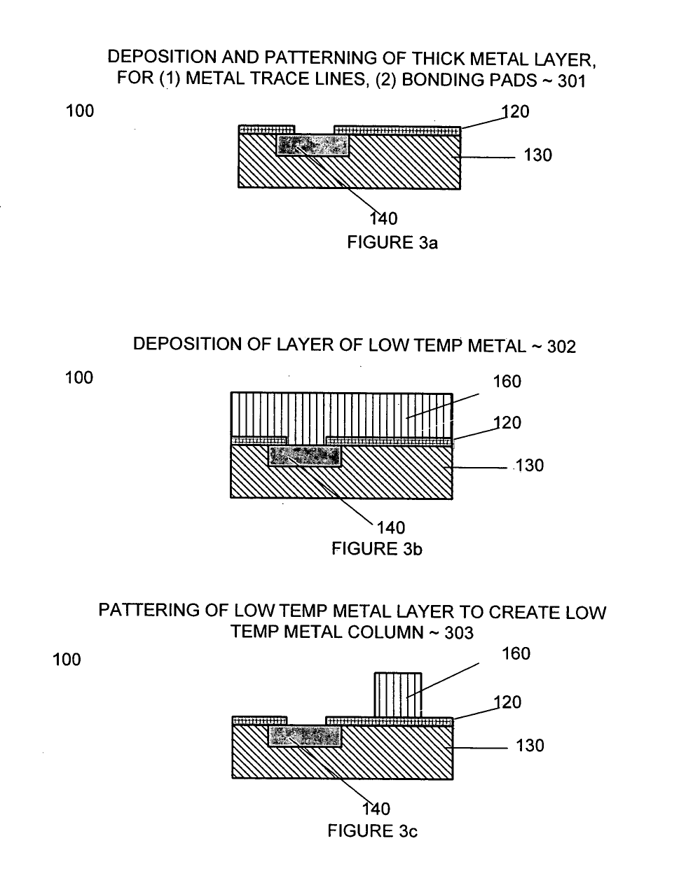

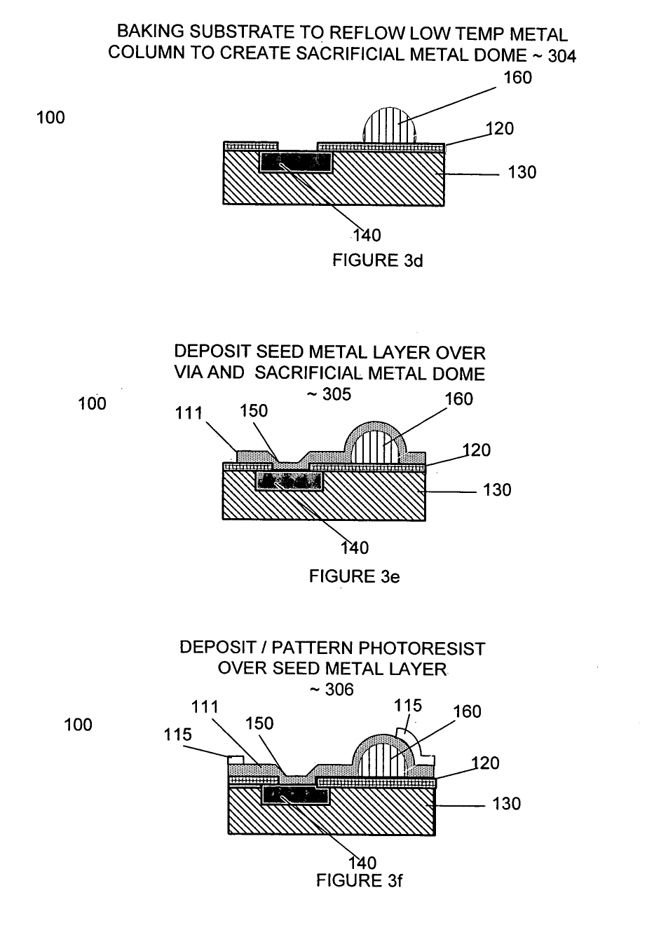

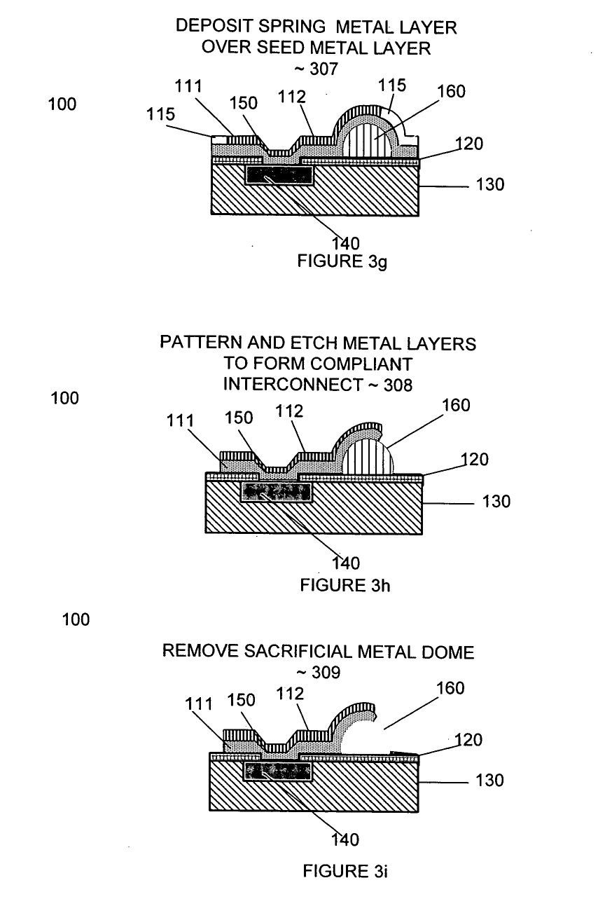

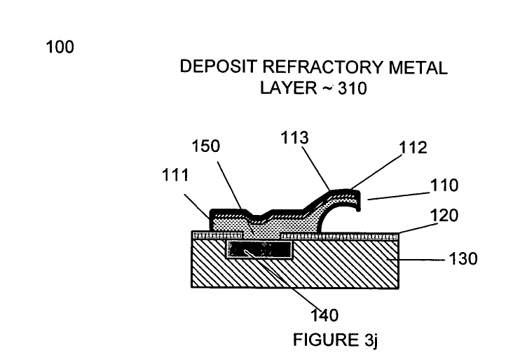

FIGS. 3a-3j illustrate a method of making component 100 in accordance with another embodiment. For the embodiment, component 100 includes a compliant interconnect with a seed metal layer, a spring metal layer, and an outer refractory metal layer.

As illustrated, the method starts with the formation of substrate 130 with pad 140 and an opening 150 exposing the pad 140 may be formed in any one of a number of techniques, op 301. In various embodiments, substrate 130 may be a silicon (Si) substrate, and passivation layer 120 may be formed employing silicon nitride (SiN), and deposited in any one of a number of techniques. In other embodiments, layer 120 may have a polyimide layer 130. The materials listed for the passivation layer 120 are illustrative only; any number of suitable materials may alternately be used to form the layer.

Then, a metal layer 160 is deposited on a top side of dielectric layer 120, op 302. The metal layer may be formed by employing a metal with low reflow temperature, such as tin (Sn), indium (In), bismuth (Bi), zinc (Zn), and other materials with like properties and alloys of these materials.

Next, metal layer 160 is patterned to create a metal column 160, op 303.

Then, metal column 160 may be reflowed into sacrificial metal dome 160 in a number of application dependent manners, op 304. The temperature and the amount of time, heat is applied, are dependent on the composition of the sacrificial metal, the size of column, and heat sensitive, if any, of the surrounding structures.

Next, for the embodiment, a seed metal layer 111 is deposited on the dielectric layer 120 over the opening 150 and the sacrificial metal dome 160, op 305. In various embodiments, seed layer 111 may be deposited by employing a method such as sputtering, chemical vapor deposition, physical vapor deposition, atomic layer deposition, electro plating and electroless plating.

Then, a layer of photo resist 115, is deposited and pattered to facilitate the formation of the spring metal layer 112, op 306.

Next, the spring metal layer of metal 112 is formed on top the seed metal layer 111, through the photo resist 115, op 307. In various embodiments, spring metal layer 112 is formed by electroless plating. In other embodiments, spring metal layer 112 is formed by electro plating.

Thereafter, the photo resist and the sacrificial metal dome 160 are removed by e.g selective etching, op 308-309.

Finally, the refractory metal layer 113 is deposited, op 310. In various embodiments, refractory metal layer 113 may be deposited on by electroless plating. In other embodiments, refractory metal layer 113 may be deposited by electro plating.

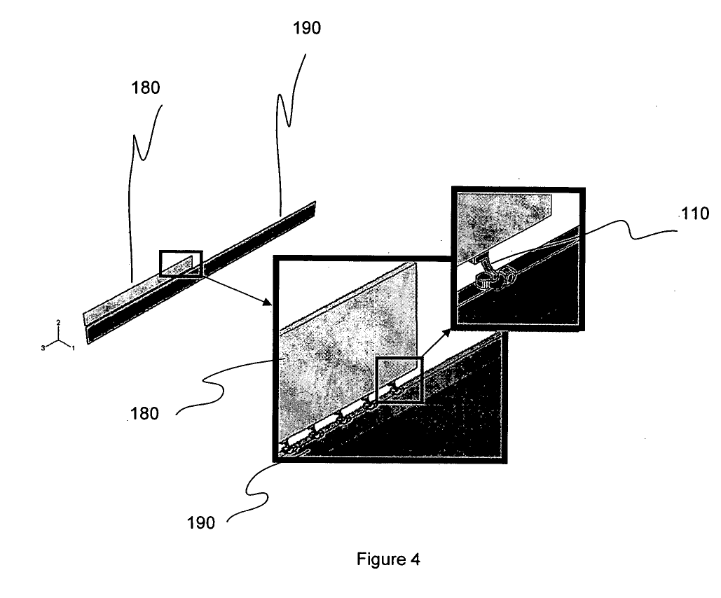

FIG. 4 illustrates a system in accordance with one embodiment. As illustrated, for the embodiment, system 400 includes computing device 402 for processing data. Computing device includes a motherboard 404. Motherboard 404 includes in particular a processor 406, a networking interface 408 coupled to a bus 410. More specifically, processor 406 is component 100 endowed with the earlier described compliant interconnects. In alternate embodiments, system 400 may include other semiconductor components having compliant interconnects formed as earlier described.

Depending on the applications, system 400 may include other components, including but are not limited to volatile and non-volatile memory, a graphics processor, a digital signal processor, a crypto processor, a chipset, mass storage (such as hard disk, compact disk (CD), digital versatile disk (DVD) and so forth), and so forth. One or more of these components may also include the earlier described compliant interconnects.

In various embodiments, system 400 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

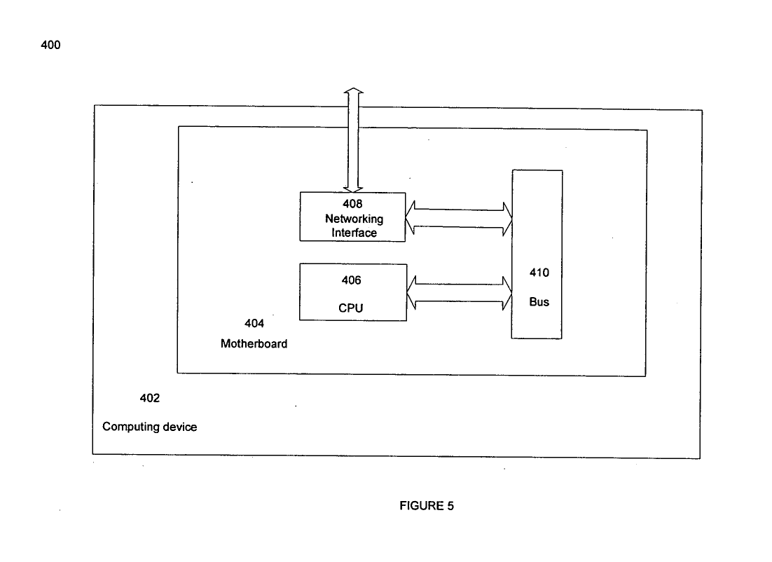

FIG. 5 illustrates a cross sectional view of a portion a die and a substrate with component 100 of FIG. 1 coupled with a substrate 510 in accordance with one embodiment. Compliant interconnect 110 of component 100 reduces the stresses in the dielectric materials on the die portion of component 100 when compared to other state of the art interconnect packages. The die portion comprises the pad 140, the passivation layer (or dielectric layer) 120 disposed on the substrate 130 with an opening 150 exposing the pad 140 illustrated in FIG. 1. The die may also comprise electrical circuits as described in other embodiments. Coupling substrates with interconnect 110 or component 100 provides modulated compliance to minimize the effects of mechanical and thermal stress on the ultra low-k ILD layers while still providing sufficient load bearing capability

Thus, it can be seen from the above descriptions, a novel component having an improved compliant interconnect, method for making such a component, and a system having such a component have been described. While the present invention has been described in terms of the foregoing embodiments, those skilled in the art will recognize that the invention is not limited to the embodiments described. The present invention can be practiced with modification and alteration within the spirit and scope of the appended claims.

Therefore, the description is to be regarded as illustrative instead of restrictive on the present invention.

1. A method to form a compliant interconnect comprising:
forming a sacrificial metal dome on top of a dielectric layer, at one side of an opening of the dielectric layer exposing a metal pad;
forming a spring metal layer of the compliant interconnect over the sacrificial metal dome and the metal pad; and
forming an outer refractory metal layer of the compliant interconnect.

2. The method of claim 1, wherein the forming of the sacrificial metal dome comprises depositing a metal on top of the dielectric layer at one side of the opening, patterning and etching the metal, and applying heat to reflow the deposited metal.

3. The method of claim 2, wherein the depositing of the metal comprises an operation selected from an operation group consisting of a sputtering operation, a chemical vapor deposition operation, an electro plating operation, and an electroless plating operation.

4. The method of claim 1, wherein the forming of the spring metal layer comprises forming a seed metal layer over the sacrificial dome, and forming the spring metal layer over the seed metal layer.

5. The method of claim 4, wherein the forming of the seed metal layer comprises depositing a seed metal layer of a seed metal composition on top of the sacrificial metal dome, the metal pad, and the dielectric layer at the other side of the opening.

6. The method of claim 5, wherein the depositing of the seed metal layer comprises an operation selected from an operation group consisting of a sputtering operation, a chemical vapor deposition operation, a physical vapor deposition operation, an atomic layer deposition operation, an electro plating operation, and an electroless plating operation.

7. The method of claim 4, wherein the forming of the spring metal layer of the compliant interconnect comprises depositing a spring metal layer of a spring metal composition on top of the seed metal layer.

8. The method of claim 7, wherein the forming of the spring metal layer comprises an operation selected from an operation group consisting of an electro plating operation and an electroless plating operation.

9. The method of claim 1, wherein the method further comprises forming a photo resist on the spring metal layer, patterning the photo resist, etching excess of the spring metal layer, and removing remainder of the photo resist.

10. The method of claim 1, wherein the method further comprises removing the sacrificial metal dome.

11. The method of claim 1, wherein the forming of the refractory metal layer of the compliant interconnect comprises an electroless plating operation.

12. The method of claim 1, wherein the refractory metal composition comprises a metal selected from a group consisting of W, Mo, Re, Ta, Nb, Zr, Hf, OS, Ir and their alloys.

13. The method of claim 12, wherein the refractory metal composition further comprises an element selected from a group consisting of P, B and N.

14. The method of claim 1, wherein the forming of the spring metal layer comprises:
forming a seed metal layer over the sacrificial dome;
forming a patterned photo resist layer over the seed metal layer; and
forming the spring metal layer through the pattern photo resist layer.

15. The method of claim 14, wherein the forming of the spring metal layer through the patterned photo resist comprises an operation selected from an operation group consisting of an electro plating operation and an electroless plating operation.

16. A compliant interconnect having:
a spring layer of a spring metal composition; and
an outer refractory metal layer of a refractory metal composition.

17. The compliant interconnect of claim 16, wherein the compliant interconnect further comprises a seed layer of seed metal composition, the spring metal layer being formed on top of the seed metal layer.

18. The compliant interconnect of claim 17, wherein the seed metal composition comprises a selected one of Al, Cu, Ti, Ni, Pt, Au, Ag, Sn, Ta, Mo, Cr, Co, and their alloys.

19. The compliant interconnect of claim 16, wherein the refractory metal composition comprises a metal selected from a group consisting of Co, Ni, Au, Pt, Pd, Ir, Os, Ru, Rh, Ag, and their alloys.

20. The compliant interconnect of claim 19, wherein the refractory metal composition further comprises a metal selected from a group consisting of W, Mo, Re, Ta, Nb, Zr, Hf, OS, Ir and their alloys.

21. The compliant interconnect of claim 20, wherein the refractory metal composition further comprises an element selected from a group consisting of P, B and N.

22. The compliant interconnect of claim 16, wherein the spring metal composition comprises a material selected an material group consisting of Al, Cu, Ti, Ni, Pt, Au, Ag, Sn, Ta, Mo, Cr, Co, and their alloys.

23. A system comprising:
a semiconductor package comprising a die, the die having a compliant interconnect with an outer refractory metal layer;
a bus coupled to the semiconductor package; and
a network interface module coupled to the bus.

24. The system of claim 23, wherein the semiconductor package comprises a semiconductor device selected for a semiconductor device group consisting of a microprocessor, a memory device, a graphics processor, a digital signal processor, and a crypto processor.

25. The system of claim 22, wherein the system is selected one of a digital versatile disk player, an audio/video media player, and a set-top box.
